(19) United States
(12) Patent Application Publication
(10) Pub. No.: US 2004/0066118 A1
(43) Pub. Date: Apr. 8, 2004

(54) Micro-reactor

(76) Inventors: Guido Pieper, Darmstadt (DE); Hanns Wurziger, Darmstadt (DE); Norbert Schwesinger, Eching (DE)

Correspondence Address: Millen White, Zelano & Branigan, Arlington Courthouse Plaza I, 2200 Clarendon Boulevard Suite 1400, Arlington, VA, 22201, US

(21) Appl. No.: 10/468,906

(22) PCT Filed: Feb. 6, 2002
(86) PCT No.: PCT/EP02/01199

(30) Foreign Application Priority Data
Feb. 28, 2001 (DE) 101 09 589.9

(51) Int. Cl. H01L 41/113

(52) U.S. Cl. 310/339; 310/215; 310/368

(57) ABSTRACT

The invention relates to a micro-reactor, which is preferably configured as a plate and preferably consists of silicon. The aim of the invention is to improve the blending of the substances that are to react. To achieve this, the reactor is provided with a mechanic coupling, comprising at least one generator of mechanical oscillations (24). The invention also relates to a device (25) for controlling the temperature of the micro-reactor.

The invention relates to a microreactor, which preferably has a plate-shaped design and preferably consists of silicon.

The development and preparation of novel substances in the area of chemistry frequently requires extensive series of experiments. For this purpose, microcomponents have been disclosed with the aid of which the experiments can be carried out using small amounts. The modular construction of these microcomponents, for example microreactors and other components for the treatment of various substances, makes assembly of systems for the respective task readily possible. Modular chemical Microsystems of this type are described in DE 198 54 096 A1 and DE 199 17 398 A1.

In order to carry out reactions in fluid phases which are not miscible with one another per se, intensive mixing with formation of large interfacial areas is necessary. This is usually achieved by means of high stirring speeds, at which the phases are brought into intensive contact with one another.

The object of the present invention is to facilitate intensive mixing of different fluid phases even on use of microcomponents.

This object is achieved in accordance with the invention by mechanical coupling to at least one mechanical vibration generator. It is preferably provided here that the at least one vibration generator is arranged on at least one side of the microreactor. The invention is also suitable for microreactors made from microstructurable materials other than silicon, for example glass, ceramic, metal or plastic.

The introduction of sound energy causes the fluid phases to mix with one another intensively with formation of large interfacial areas. If it is ensured that all substances remain in the dissolved liquid phase and do not precipitate during passage through the microcomponents, all two- or multi-phase systems can be used for carrying out the reaction. These are, in particular, water/water-insoluble liquids (methylene chloride, chloroform, tetrachloromethane or other halogenated (fluorinated) hydrocarbons, aliphatic compounds, such as pentane, hexane, cyclohexane, heptane and higher aliphatic compounds, and aromatic compounds, such as benzene, toluene, xylene, mesitylene, etc., benzine, ether; systems which are generally known to the person skilled in the art). As examples of reaction types, mention may be made of all alkylations and etherifications using commercially available reagents and solvents, in particular:

alkyl, allyl, propargyl and arylmethyl halides and sulfonates as alkylating agents,

chlorinated hydrocarbons as water-immiscible solvents,

aqueous alkalis as bases,

tertiary ammonium compounds as catalysts.

The advantage of alkylation and etherification in microfluid systems consists in better mass and heat transport, improved control of the reaction time and increased safety in the handling of hazardous materials. This is due to the very small amounts of reagent present in the system. The good mixing of the reagents achieved by means of the invention and the continuous procedure facilitated by the use of the microfluid system make a considerable contribution towards better control of the reaction conditions. Protective-gas conditions can also be implemented better with the small dimensions of the system.

It is preferably provided in the microreactor according to the invention that the vibration generator is adhesively bonded on. Suitable adhesives are, in particular, fast-curing epoxy adhesives. However, other techniques, for example thick-film techniques, are also suitable.

An advantageous embodiment of the microreactor according to the invention can be produced in a compact, robust and simple manner if the vibration generator is a piezoelectric transducer.

Another advantageous embodiment consists in that the vibration generator can be excited at a frequency in the range from 500 Hz to 50,000 Hz, preferably from 750 Hz to 16,000 Hz. Depending on the geometrical dimensions of the microreactor and the cavities present therein, other frequencies can also be used.

The frequency range indicated above has proven successful in a design which consists in that a reaction channel having a length of essentially 0.30 m and a volume of essentially 80 μl is arranged in the microreactor. It is preferably provided in the microreactor according to the invention that a micromixer is installed upstream of the microreactor.

In order to improve the chemical reactions further, it may furthermore be provided in the microreactor according to the invention that a device for temperature control is installed on at least one side.

In this embodiment, the device for temperature control can be a resistance heater, preferably a conductor track, or a Peltier element.

For reactions for which no particular measures for mixing are necessary, but for which certain temperatures are advantageous or necessary, the invention may also be designed without a mechanical vibration generator in such a way that a device for temperature control is installed on at least one side. It is preferably provided here that a conductor track serving as resistance heater occupies at least part of the surface of the microreactor in a meander shape.

Illustrative embodiments of the invention are explained in greater detail in the following description and are shown in the drawing with reference to a number of figures, in which:

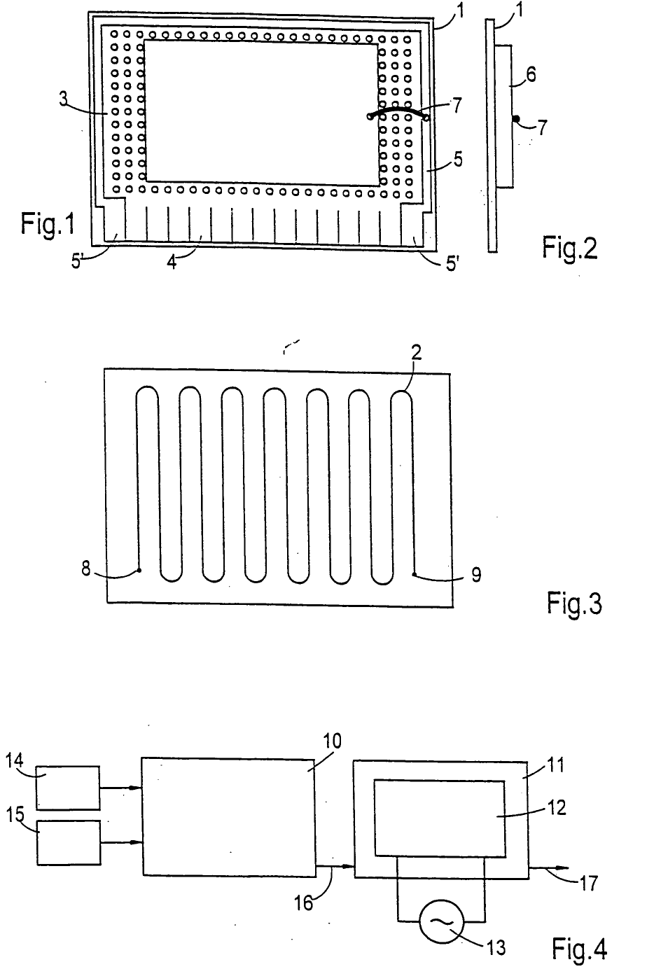

FIG. 1, FIG. 2 and FIG. 3 show three views of a first illustrative embodiment,

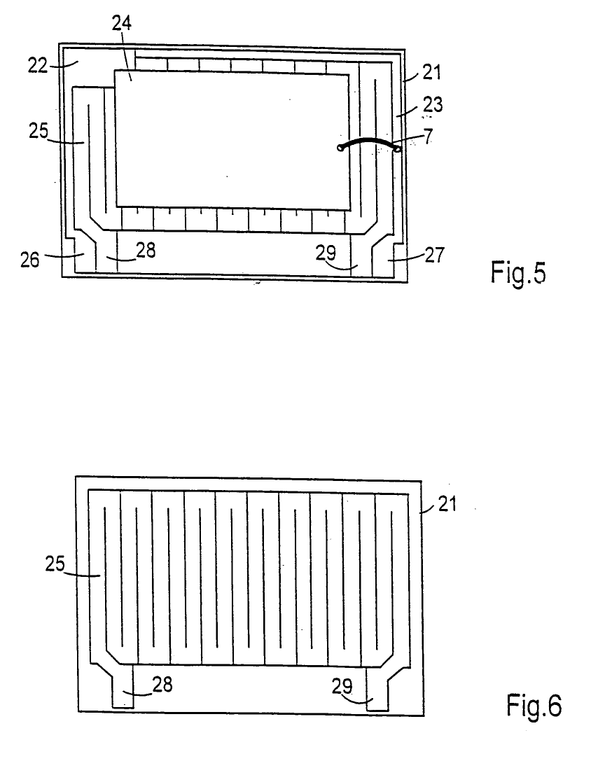

FIG. 4 shows a device having a microreactor according to the invention,

FIG. 5 shows a second illustrative embodiment, and

FIG. 6 shows a third illustrative embodiment.

The same parts are provided with the same reference symbols in the figures.

The illustrative embodiment in FIG. 2 consists of a microcomponent 1, which is formed by a silicon plate 1 with a channel 2 produced by anisotropic etching. The course of the channel 2 with connection apertures 8, 9 is indicated in FIG. 3. Microcomponents having only one channel usually serve as residence zones and, through the use of sound energy, are used in accordance with the invention as reactors. To this end, a static mixer 10 having two inlets and one outlet can be installed upstream of the microcomponent 11 in FIG. 4. However, both the mixer and the microreactor according to the invention can be accommodated on a single silicon plate.

Electrically conducting layers are located on the side of the microcomponent 1 shown in FIG. 1. The first electrically conducting layer 3 has a two-dimensional design and has a number of contact surfaces 4. A strip-shaped conductor track 5 runs along the edge of microcomponent 1 and likewise has contact surfaces 5′ at its ends.

A piezoelectric transducer 6 is adhesively bonded to the conductive layer 3. One of its connections is connected in an electrically conducting manner (not shown) to the conductive layer 3. The piezoelectric transducer 6 connection facing away from microcomponent 1 is connected to the conductor track 5 via a lead 7. By insertion of the microreactor shown in FIG. 1 into a holder provided with contact springs—for example in accordance with DE 198 54 069 A1—alternating voltage can be supplied to the piezoelectric transducer 6 by a generator.

FIG. 4 shows a diagrammatic portrayal with a static mixer 10 and a reactor 11 designed in accordance with the invention, whose piezoelectric transducer 12 is connected to an alternating-current generator 13. The substances to be mixed can be fed to the mixer from stock vessels 14, 15. The mixer 10 and the reactor 11 are connected to one another with the aid of a line 16. The starting material can be removed from the reactor 11 at 17.

FIG. 5 shows a second illustrative embodiment in which, in addition to conductor tracks 22, 23 for supplying the piezoelectric transducer 24, a meander-shaped conductor track 25 has been applied as heater to the microcomponent 21. Connections 26, 27 are provided for the piezoelectric transducer and further connections 28, 29 are provided for the heater.

FIG. 6 shows an illustrative embodiment in which a meander-shaped conductor track 25 has been applied as heater to a microcomponent 21, with two connections 28, 29.

1. Microreactor, which preferably has a plate-shaped design and preferably consists of silicon, characterised by mechanical coupling to at least one generator (6, 12, 24) of mechanical vibrations.

2. Microreactor according to claim 1, characterised in that the at least one vibration generator (6, 12, 24) is arranged on at least one side of the microreactor.

3. Microreactor according to claim 2, characterised in that the vibration generator (6, 12, 24) is adhesively bonded on.

4. Microreactor according to one of the preceding claims, characterised in that the vibration generator is a piezoelectric transducer (6, 12, 24).

5. Microreactor according to one of the preceding claims, characterised in that the vibration generator (6, 12, 24) can be excited at a frequency in the range from 500 Hz to 50,000 Hz, preferably from 750 Hz to 16,000 Hz.

6. Microreactor according to claim 5, characterised in that a reaction channel (2) having a length of essentially 0.30 m and a volume of essentially 80 μl is arranged in the microreactor.

7. Microreactor according to one of the preceding claims, characterised in that a micromixer (10) is installed upstream of the microreactor (11).

8. Microreactor according to one of the preceding claims, characterised in that a device for temperature control is furthermore installed on at least one side.

9. Microreactor according to claim 8, characterised in that the device for temperature control is a resistance heater, preferably a conductor track (25).

10. Microreactor according to claim 8, characterised in that the device for temperature control is a Peltier element.

11. Microreactor, which preferably has a plate-shaped design and preferably consists of silicon, characterised in that a device for temperature control (25) is installed on at least one side.

12. Microreactor according to claim 11, characterised in that a conductor track (25) serving as resistance heater occupies at least part of the surface of the microreactor in a meander shape.
